(19) United States
(12) Patent Application Publication
(10) Pub. No.: US 2024/0151258 A1
(43) Pub. Date: May 9, 2024

(54) FASTENER FOR SERVER CABINET AND SERVER CABINET

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Tao LIU, Zhangjiakou City (CN)

(21) Appl. No.: 18/500,056

(22) Filed: Nov. 1, 2023

(30) Foreign Application Priority Data
Nov. 3, 2022 (CN) 202211371864.5

(51) Int. Cl. F16B 21/02

(52) U.S. Cl. CPC F16B 21/02; H05K 7/1488

(57) ABSTRACT

Embodiments of the present disclosure provide a fastener for a server cabinet and the server cabinet. The fastener for the server cabinet includes an upper limit member, a fastening spring, a lower limit member, and a fastening pin rod. The present disclosure relates to the field of server cabinet technology. The fastener for the server cabinet provided in the present disclosure is small in volume, compact and reliable in structure, stable in fastening, and suitable for fastening connection in narrow space. The fastener may easily achieve fastening or unfastening operation by rotating 90° without restriction of a rotation direction, which is fast in installation and convenient for disassembly and assembly.

### CROSSREFERENCE TO RELATED APPLICATION

This application claims priority to Chinese Patent Application No. 202211371864.5 titled “FASTENER FOR SERVER CABINET AND SERVER CABINET” and filed to the China National Intellectual Property Administration on Nov. 03, 2022, the entire contents of which are incorporated herein by reference.

### TECHNICAL FIELD

The present disclosure relates to the field of server cabinets, and more particularly, to a fastener for a server cabinet and the server cabinet.

### BACKGROUND

In the era of big data explosion, especially with the development of Artificial Intelligence (AI) technologies, data size grows geometrically. In a data center for computing and storing these data, servers are widely used.

To ensure stable and reliable operation of the servers and other devices, the servers are generally placed and fixed in server cabinets or other containers. In the event of malfunctions and in need of maintenance during the use of the servers, it is required to remove the servers from the cabinets or other containers. Traditional fastening methods are inefficient in maintenance and require the use of welding or other processes during manufacturing, making them more complex. Moreover, fasteners for some server cabinets are generally paired with dedicated buckles, making disassembly and assembly cumbersome.

As can be seen from the above description, the fasteners for fixing the servers at present are large in volume, complex in structure, required for dedicated buckle accessories, cumbersome in disassembly and assembly, poor in reliability, and difficulty in maintenance and replacement.

### SUMMARY

To solve some or all of the problems existing in the prior art, embodiments of the present disclosure provide a fastener for a server cabinet and the server cabinet. The technical solutions are as follows.

In a first aspect, there is provided a fastener for a server cabinet, which includes an upper limit member, a fastening spring, a lower limit member, and a fastening pin rod.

The upper limit member is provided with a limit hole, a rotation groove, and an anti -rotation limiter.

The fastening pin rod is provided with a pin head.

The lower limit member is provided with an upper retainer ring, a retainer ring section, a hollow sleeve, and a bottom installation section.

The pin head of the fastening pin rod is installed in the limit hole of the upper limit member to form an upper component through interference fit.

The lower limit member is sleeved on the fastening pin rod through the hollow sleeve. The fastening spring is sleeved on the fastening pin rod, and an upper end of the fastening spring supports and touches the pin head, and a lower end of the fastening spring supports and touches a bottom inner end face of the lower limit member.

A height of the rotation groove is greater than a thickness of the upper retainer ring, and the anti-rotation limiter forms a clearance fit with the retainer ring section, such that the upper retainer ring can rotate in the rotation groove and slide along an axis in the anti-rotation limiter.

Further, a bottom of the upper limit member (1) is further provided with a claw-type buckle (9) configured to limit a slide limit of the lower limit member (3) along the axis.

Further, the limit hole of the upper limit member comprises an upper limit hole (5) and a lower limit hole (6), the pin head (13) comprises an upper pin head and a lower pin head, and the lower pin head protrudes from the upper pin head. A cross section of the upper limit hole (5) and a cross section of the upper pin head are cyclotomic, and a cross section of the lower limit hole (6) and a cross section of the lower pin head are round, to achieve tight connection through interference fit respectively.

Further, an inner wall of the upper limit member is provided with a limit boss (12) every 90 degrees, and the upper retainer ring (19) is also provided with an arc groove (25) of the retainer ring.

When the upper retainer ring (19) rotates in the rotation groove (7), the limit boss forms a transition fit with the arc groove of the retainer ring.

Further, the upper limit member (1) is also provided with an anti-slip knurled lug and a rotation indicator arrow.

Further, a bottom of the fastening pin rod (4) is also provided with a T-shaped lock head (17), and the T-shaped lock head (17) is provided with a tool slot (18).

Further, the fastening spring (2) is a compression spring.

Further, the upper limit member (1) is made of a plastic material; and the fastening spring (2), the lower limit member (3) and the fastening pin rod (4) are made of metal materials.

In a second aspect, there is provided a server cabinet, which is equipped with the fastener as described in the first aspect.

The fastener for the server cabinet provided in the present disclosure is small in volume, compact and reliable in structure, stable in fastening, and suitable for fastening connection in narrow space. When in use, the fastener may be manually driven or driven by means of a tool to easily achieve fastening or unfastening operation by rotating 90° without restriction of a rotation direction, which is fast in installation and convenient for disassembly and assembly. The fastener is reusable and is convenient for maintenance and replacement, without dedicated buckle accessories. Due to the action of the compression spring, a relative position between the upper limit member and the lower limit member may vary depending on thicknesses of fixed plates, making the fastener suitable for complex operating environments with different thicknesses of plates.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of a fastener for a server cabinet provided in an embodiment of the present disclosure;

FIG. 2 is an AA cross-sectional diagram of a fastener for a server cabinet provided in an embodiment of the present disclosure;

FIG. 3 is a schematic bottom perspective view of a fastener for a server cabinet provided in an embodiment of the present disclosure;

FIG. 4 is a schematic top perspective view of a fastener for a server cabinet provided in an embodiment of the present disclosure;

FIG. 5 is a schematic top perspective view of an upper limit member of a fastener for a server cabinet provided in an embodiment of the present disclosure;

FIG. 6 is an AA cross-sectional diagram of an upper limit member of a fastener for a server cabinet provided in an embodiment of the present disclosure;

FIG. 7 is a BB cross-sectional diagram of an upper limit member of a fastener for a server cabinet provided in an embodiment of the present disclosure;

FIG. 8 is a schematic bottom perspective view of an upper limit member of a fastener for a server cabinet provided in an embodiment of the present disclosure;

FIG. 9 is a schematic isometric view of an upper limit member of a fastener for a server cabinet provided in an embodiment of the present disclosure;

FIG. 10 is a schematic bottom perspective view of a fastening pin rod of a fastener for a server cabinet provided in an embodiment of the present disclosure;

FIG. 11 is a schematic front view of a fastening pin rod of a fastener for a server cabinet provided in an embodiment of the present disclosure;

FIG. 12 is a schematic right view of a fastening pin rod of a fastener for a server cabinet provided in an embodiment of the present disclosure;

FIG. 13 is a schematic top perspective view of a fastening pin rod of a fastener for a server cabinet provided in an embodiment of the present disclosure;

FIG. 14 is a schematic top perspective view of a lower limit member of a fastener for a server cabinet provided in an embodiment of the present disclosure;

FIG. 15 is a schematic front view of a lower limit member of a fastener for a server cabinet provided in an embodiment of the present disclosure;

FIG. 16 is an AA cross-sectional diagram of a lower limit member of a fastener for a server cabinet provided in an embodiment of the present disclosure;

FIG. 17 is a schematic right view of a lower limit member of a fastener for a server cabinet provided in an embodiment of the present disclosure;

FIG. 18 is a BB cross-sectional diagram of a lower limit member of a fastener for a server cabinet provided in an embodiment of the present disclosure; and

FIG. 19 is a schematic isometric view of a lower limit member of a fastener for a server cabinet provided in an embodiment of the present disclosure.

### REFERENCE NUMBERS IN THE ATTACHED DRAWINGS

upper limit member 1, fastening spring 2, lower limit member 3, fastening pin rod 4, upper limit hole 5 of the upper limit member, lower limit hole 6 of the upper limit member, rotation groove 7, anti-rotation limiter 8, claw-type buckle 9, anti-slip knurled lug 10, rotation indicator arrow 11, limit boss 12, pin head 13, section 14 of the pin head, an upper part 15 of a polished rod, a lower part 16 of the polished rod, T-shaped lock head 17, tool slot 18, upper retainer ring 19 of the lower limit member, hollow sleeve 20, retainer ring section 21 of the lower limit member, chamfer 22 of the retainer ring, transition fillet 23 of the retainer ring, bottom installation section 24, and arc groove 25 of the retainer ring.

### DETAILED DESCRIPTION

To make the objectives, technical solutions and advantages of the present disclosure clearer, the embodiments of the present disclosure will be further described below in detail with reference to the accompanying drawings. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

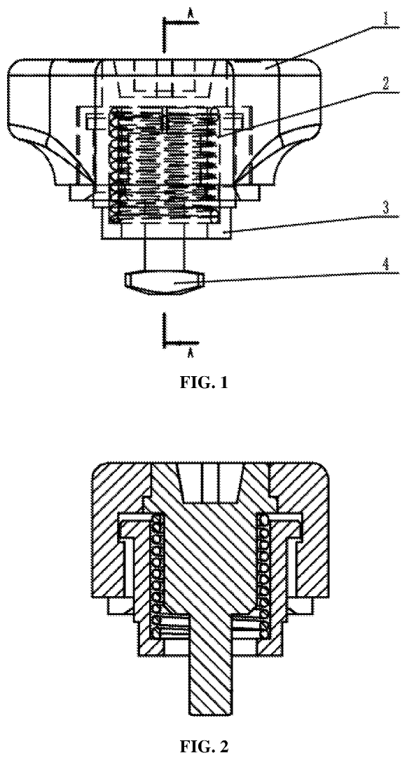

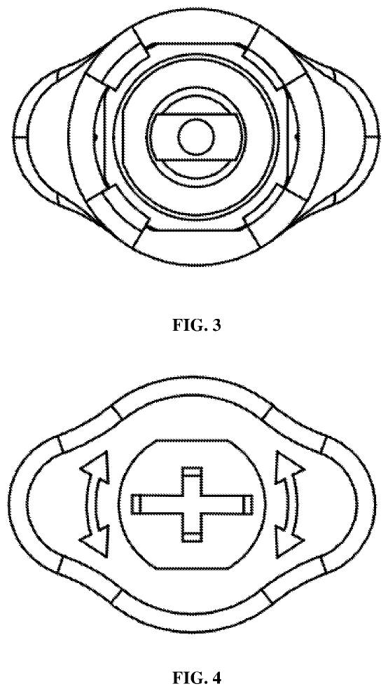

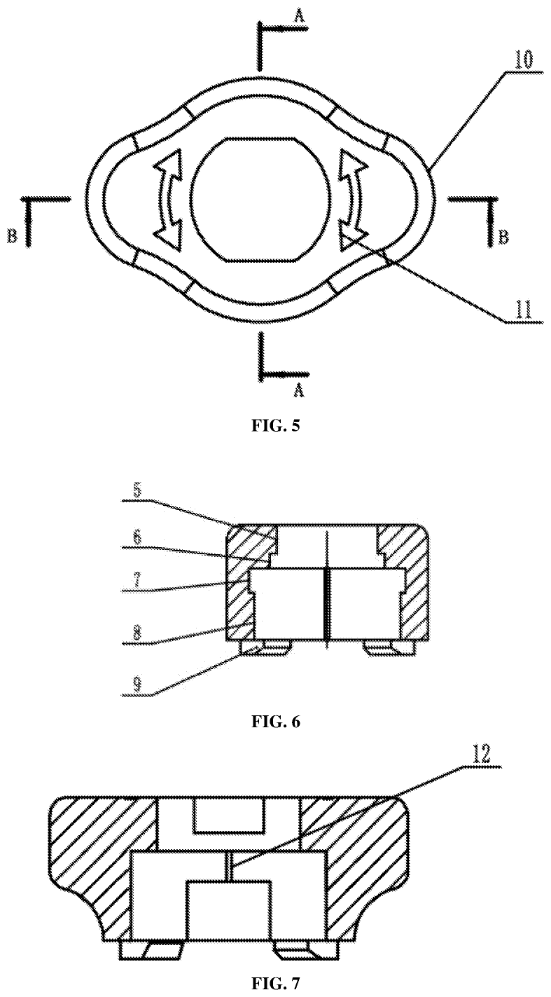

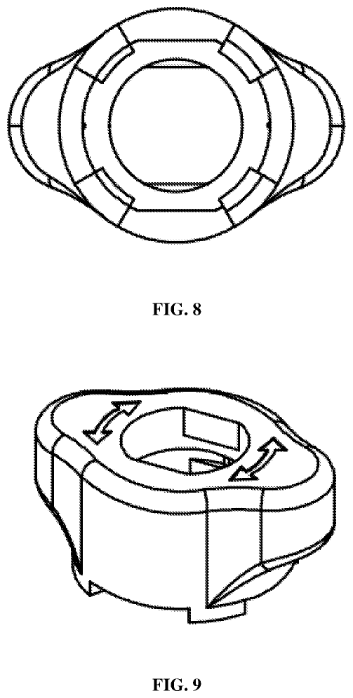

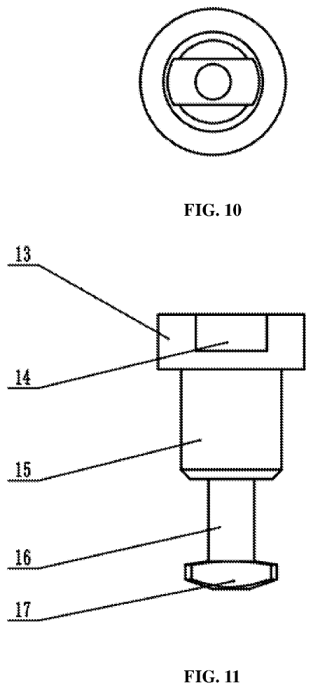

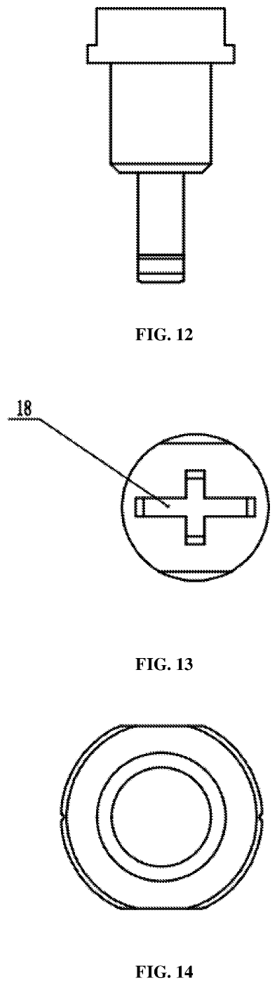

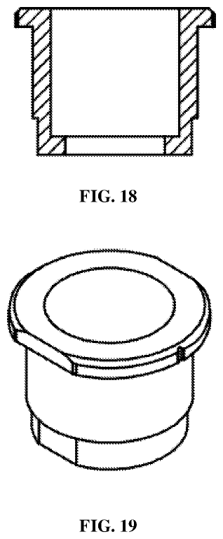

The embodiments of the present disclosure provide a fastener for a server cabinet. As shown in FIGS. 1 to 19, the fastener for the server cabinet provided by the present disclosure may include an upper limit member 1, a fastening spring 2, a lower limit member 3, and a fastening pin rod 4. The upper limit member 1 is provided with a limit hole, a rotation groove 7, and an anti-rotation limiter 8. The fastening pin rod 4 is provided with a pin head 13. The lower limit member 3 is provided with an upper retainer ring 19, a retainer ring section 21, a hollow sleeve 20, and a bottom installation section 24. The pin head 13 of the fastening pin rod is installed in the limit hole of the upper limit member 1 to form an upper component through interference fit. The lower limit member 3 is sleeved on the fastening pin rod 4 through the hollow sleeve 20. The fastening spring 2 is sleeved on the fastening pin rod 4, and an upper end of the fastening spring 2 supports and touches the pin head 13, and a lower end of the fastening spring 2 supports and touches a bottom inner end face of the lower limit member 3. A height of the rotation groove 7 is greater than a thickness of the upper retainer ring 19, and the anti-rotation limiter 8 forms a clearance fit with the retainer ring section 21, such that the upper retainer ring 19 can rotate in the rotation groove 7 and slide along an axis in the anti-rotation limiter 8.

Alternatively, a bottom of the upper limit member 1 is further provided with a claw-type buckle 9 configured to limit a slide limit of the lower limit member 3 along the axis.

In one embodiment, the height of the rotation groove 7 is greater than the thickness of the upper retainer ring 19 of the lower limit member 3, and a rotation operation cannot be carried out unless when the upper retainer ring 19 is inside the rotation groove 7. The anti-rotation limiter 8 forms a clearance fit with the retainer ring section 21 of the lower limit member, allowing a combination of the upper limit member 1 and the fastening pin rod 4 to slide relative to the lower limit member through expansion and contraction of the compression spring 2. Four claw-type buckles 9 are arranged at the bottom of the upper limit member, and are evenly distributed at 90 degrees, with their claw tip parts protruding (smaller than a minimum internal hollow diameter of the upper limit member).

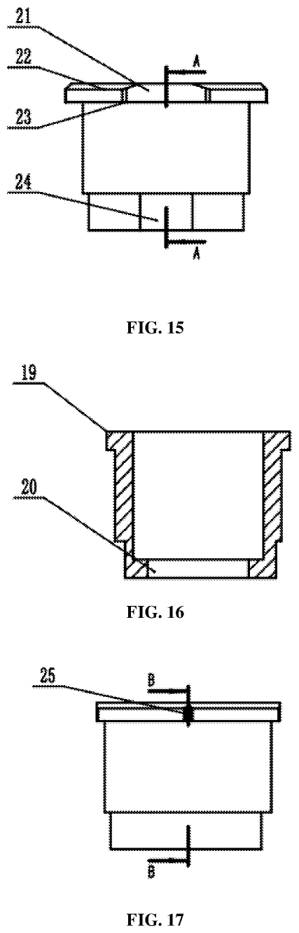

Referring to FIGS. 14 and 15, a cross section of the upper retainer ring of the lower limit member 3 may be two-sided cyclotomic, and a chamfer is provided at the top to facilitate fitting with the claw-type buckle of the upper limit member. An outer diameter of the upper retainer ring is slightly smaller than an inner diameter of the upper limit member, and arc notches (also known as arc grooves) are evenly distributed at 90 degrees on a side. A middle part of the lower limit member 3 is a cylindrical hollow structure, with an outer diameter smaller than the outer diameter of the upper retainer ring and an inner diameter larger than the outer diameter of the compression spring. The bottom of the lower limit member 3 has a circular through hole structure, where an inner diameter of the through hole is smaller than the inner diameter of the compression spring and is larger than a length of the T-shaped lock head of the fastening pin rod. An outer side of the bottom is a cyclotomic structure forming an interference limit fit with other components needing to be fixed. In this way, due to the structure of the chamfer 22 of the retainer ring, the lower limit member 3 may easily be pushed into the claw-type buckle 9 to complete the assembly. The transition fillet 23 of the retainer ring allows the combination of the upper limit member 1 and the fastening pin rod 4 to achieve smooth transition during rotation, thus eliminating component wear. In addition, the bottom installation section 24 is used to fasten a base body, such that the base body does not rotate.

The base body may be the server cabinet or a server. Before the aforementioned fastener is installed, a fixed plate of the server cabinet or server may be pre-drilled according to size requirements of the bottom installation section 24.

Alternatively, the limit hole of the upper limit member includes an upper limit hole 5 and a lower limit hole 6, and the pin head 13 includes an upper pin head and a lower pin head, where the lower pin head protrudes from the upper pin head. A cross section of the upper limit hole 5 and a cross section of the upper pin head are cyclotomic, and a cross section of the lower limit hole 6 and a cross section of the lower pin head are round, to achieve tight connection through interference fit respectively.

In one embodiment, the pin head of the fastening pin rod is comprised of an upper part and a lower part. As a cyclotomic structure, the upper part forms an interference fit with the limit hole of the upper limit member to play a limiting action along an XY direction. Protruding from the upper part, the lower part forms an interference fit with the limit hole of the upper limit member to play a limiting action along a Z direction.

Alternatively, an inner wall of the upper limit member is provided with a limit boss 12 every 90 degrees, and the upper retainer ring 19 is further provided with an arc groove 25 of the retainer ring. When the upper retainer ring 19 rotates in the rotation groove 7, the limit boss forms a transition fit with the arc groove of the retainer ring.

In one embodiment, a lower limiter of the upper limit member and an upper limiter 5 of the upper limit member whose cross section is cyclotomic form an interference fit with the pin head, and a section of the upper limiter 5 forms a fit with a section 14 of the pin head. This structure can completely fasten the upper limit member 1 and the fastening pin rod 4. Four limit bosses 12 are arranged on the inner wall of the upper limit member and are evenly distributed at 90 degrees, to fit with the arc groove 25 of the retainer ring of the lower limit member 3, such that the combination of the upper limit member 1 and the fastening pin rod 4 can move within a single rotation range of 90 degrees. As shown in FIG. 14, number of the arc grooves 25 of the retainer ring may be two.

Alternatively, the upper limit member 1 is further provided with an anti-slip knurled lug and a rotation indicator arrow.

In one embodiment, the upper limit member 1 is a hollow body and is provided with two anti-slip knurled lugs 10 at two ends on the top. This structure allows to achieve fastening or unfastening operation manually, and the anti-slip knurled lugs are advantageous to increasing friction between fingers and the quick-lock fastening component, making the operation more labor-saving; The top is equipped with a rotation indicator arrow 11, indicating that the quick-lock fastening component can rotate 360 degrees by taking a Z-axis as a central axis.

Alternatively, a bottom of the fastening pin rod 4 is further provided with a T-shaped shaped lock head 17, and the T-shaped lock head 17 is provided with a tool slot 18.

In one embodiment, a diameter of an upper part 15 of a polished rod of the fastening pin rod 4 is slightly smaller than the inner diameter of the compression spring, providing a supporting role for the compression spring, and a diameter of a lower part 16 of the polished rod may be equal to a width of the T-shaped lock head 17. A length of the T-shaped lock head 17 is greater than the diameter of the upper part 15 of the polished rod and is greater than the diameter of the lower part 16 of the polished rod, the width of the T-shaped lock head may be equal to the diameter of the lower part 16 of the polished rod, and the length of the T-shaped lock head may be twice the width. The upper part and the lower part along a thickness direction (also known as an axis direction) may have inclined planes, and a maximum thickness may be equal to the width.

Alternatively, the fastening spring 2 is a compression spring.

In one embodiment, the outer diameter of the compression spring is smaller than the inner diameter of the lower limit member, the inner diameter of the compression spring is smaller than the length of the T-shaped lock head of the fastening pin rod and is greater than the inner diameter of the through hole (i.e. the hollow sleeve 20 of the lower limit member) of the lower limit member. A wire diameter and number of turns can be calculated to meet requirements of an elastic range from 3 N to 5 N.

Alternatively, the upper limit member 1 is made of a plastic material; and the fastening spring 2, the lower limit member 3 and the fastening pin rod 4 are made of metal materials.

It is to be understood that metals of the same material may exacerbate wear. Combination of the metals and the plastics can effectively improve wear resistance between various parts of the fastener. The upper limit member made of the plastic materials can also effectively alleviate impact forces during transmission and reduce noises generated during disassembly and assembly.

In one embodiment, the upper limit member 1 may be made of polyvinyl chloride; and the fastening spring 2, the lower limit member 3 and the fastening pin rod 4 may be made of stainless steel. Moreover, surfaces of the stainless steel may be passivated to form an oxide layer on the surface of the fastening spring 2, of the lower limit member 3, and of the fastening pin rod 4, thereby achieving effects of preventing corrosion.

Based on the same technical concept, the embodiments of the present disclosure also provide a server cabinet, which is equipped with the aforementioned fastener.

In one implementation, the aforementioned fastener for the server cabinet may be used as follows.

(1) First, the fastening pin rod 4 is vertically pressed into the upper limit member 1 for fixation by using installation tools to form the upper component.

(2) The compression spring 2 is installed from the T-shaped lock head of the fastening pin rod 4.

(3) The retainer ring of the lower limit member 3 is easily pushed into the claw-type buckle 9 of the upper limit member 1 to complete the assembly.

(4) A bottom installation part of the quick-lock fastening component assembled in the above three steps is vertically pressed into the base body for fixation by using the installation tools, thereby completing the use and installation of the quick-lock fastening component mentioned in the present disclosure.

(5) The upper component in Step (1) is pressed down. Next, when the upper component is manually rotated or rotated 90° in the tool slot 18 by using a tool, the limit boss 12 slides into the arc groove 25 of the upper retainer ring 19, and the compression spring 2 is compressed, thereby completing a locking action, where a locking state is shown in FIG. 1. The upper component in Step (1) is pressed down again, Next, when the upper component is manually rotated or rotated 90° in the tool slot 18 by using the tool, the limit boss 12 slides into the arc groove 25 of the upper retainer ring 19, and the compression spring 2 springs up, thereby completing an unfastening action.

The fastener for the server cabinet provided in the present disclosure is small in volume, compact and reliable in structure, stable in fastening, and suitable for fastening connection in narrow space. When in use, the fastener may be manually driven or driven by means of a tool to easily achieve fastening or unfastening operation by rotating 90° without restriction of a rotation direction, which is fast in installation and convenient for disassembly and assembly. The fastener is reusable and is convenient for maintenance and replacement, without dedicated buckle accessories. Due to the action of the compression spring, a relative position between the upper limit member and the lower limit member may vary depending on thicknesses of fixed plates, making the fastener suitable for complex operating environments with different thicknesses of plates.

The embodiments described above are merely preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A fastener for a server cabinet, comprising an upper limit member (1), a fastening spring (2), a lower limit member (3), and a fastening pin rod (4); wherein the upper limit member (1) is provided with a limit hole, a rotation groove (7), and an anti-rotation limiter (8);
the fastening pin rod (4) is provided with a pin head (13);
the lower limit member (3) is provided with an upper retainer ring (19), a retainer ring section (21), a hollow sleeve (20), and a bottom installation section (24);
the pin head (13) of the fastening pin rod is installed in the limit hole of the upper limit member (1) to form an upper component through interference fit;
the lower limit member (3) is sleeved on the fastening pin rod (4) through the hollow sleeve (20); the fastening spring (2) is sleeved on the fastening pin rod (4), and an upper end of the fastening spring (2) supports and touches the pin head (13), and a lower end of the fastening spring (2) supports and touches a bottom inner end face of the lower limit member (3); and
a height of the rotation groove (7) is greater than a thickness of the upper retainer ring (19), and the anti-rotation limiter (8) forms a clearance fit with the retainer ring section (21), such that the upper retainer ring (19) can rotate in the rotation groove (7) and slide along an axis in the anti-rotation limiter (8).

2. The fastener as claimed in claim 1, wherein a bottom of the upper limit member (1) is further provided with a claw-type buckle (9) configured to limit a slide limit of the lower limit member (3) along the axis.

3. The fastener as claimed in claim 1, wherein the limit hole of the upper limit member comprises an upper limit hole (5) and a lower limit hole (6), the pin head (13) comprises an upper pin head and a lower pin head, and the lower pin head protrudes from the upper pin head; and a cross section of the upper limit hole (5) and a cross section of the upper pin head are cyclotomic, and a cross section of the lower limit hole (6) and a cross section of the lower pin head are round, to achieve tight connection through interference fit respectively.

4. The fastener as claimed in claim 1, wherein an inner wall of the upper limit member is provided with a limit boss (12) every 90 degrees, and the upper retainer ring (19) is further provided with an arc groove (25) of the retainer ring; and
when the upper retainer ring (19) rotates in the rotation groove (7), the limit boss forms a transition fit with the arc groove of the retainer ring.

5. The fastener as claimed in claim 1, wherein the upper limit member (1) is further provided with an anti-slip knurled lug and a rotation indicator arrow.

6. The fastener as claimed in claim 1, wherein a bottom of the fastening pin rod (4) is further provided with a T-shaped lock head (17), and the T-shaped lock head (17) is provided with a tool slot (18).

7. The fastener as claimed in claim 1, wherein the fastening spring (2) is a compression spring.

8. The fastener as claimed in claim 1, wherein the upper limit member (1) is made of a plastic material; and the fastening spring (2), the lower limit member (3) and the fastening pin rod (4) are made of metal materials.

9. A server cabinet comprising a fastener, which comprises an upper limit member (1), a fastening spring (2), a lower limit member (3), and a fastening pin rod (4); wherein the upper limit member (1) is provided with a limit hole, a rotation groove (7), and an anti-rotation limiter (8);
the fastening pin rod (4) is provided with a pin head (13);
the lower limit member (3) is provided with an upper retainer ring (19), a retainer ring section (21), a hollow sleeve (20), and a bottom installation section (24);
the pin head (13) of the fastening pin rod is installed in the limit hole of the upper limit member (1) to form an upper component through interference fit;
the lower limit member (3) is sleeved on the fastening pin rod (4) through the hollow sleeve (20); the fastening spring (2) is sleeved on the fastening pin rod (4), and an upper end of the fastening spring (2) supports and touches the pin head (13), and a lower end of the fastening spring (2) supports and touches a bottom inner end face of the lower limit member (3); and
a height of the rotation groove (7) is greater than a thickness of the upper retainer ring (19), and the anti-rotation limiter (8) forms a clearance fit with the retainer ring section (21), such that the upper retainer ring (19) can rotate in the rotation groove (7) and slide along an axis in the anti-rotation limiter (8).

10. The server cabinet as claimed in claim 9, wherein a bottom of the upper limit member (1) is further provided with a claw-type buckle (9) configured to limit a slide limit of the lower limit member (3) along the axis.

11. The server cabinet as claimed in claim 9, wherein the limit hole of the upper limit member comprises an upper limit hole (5) and a lower limit hole (6), the pin head (13) comprises an upper pin head and a lower pin head, and the lower pin head protrudes from the upper pin head; and a cross section of the upper limit hole (5) and a cross section of the upper pin head are cyclotomic, and a cross section of the lower limit hole (6) and a cross section of the lower pin head are round, to achieve tight connection through interference fit respectively.

12. The server cabinet as claimed in claim 9, wherein an inner wall of the upper limit member is provided with a limit boss (12) every 90 degrees, and the upper retainer ring (19) is further provided with an arc groove (25) of the retainer ring; and
when the upper retainer ring (19) rotates in the rotation groove (7), the limit boss forms a transition fit with the arc groove of the retainer ring.

13. The server cabinet as claimed in claim 9, wherein the upper limit member (1) is further provided with an anti-slip knurled lug and a rotation indicator arrow.

14. The server cabinet as claimed in claim 9, wherein a bottom of the fastening pin rod (4) is further provided with a T-shaped lock head (17), and the T-shaped lock head (17) is provided with a tool slot (18).

15. The server cabinet as claimed in claim 9, wherein the fastening spring (2) is a compression spring.

16. The server cabinet as claimed in claim 9, wherein the upper limit member (1) is made of a plastic material; and the fastening spring (2), the lower limit member (3) and the fastening pin rod (4) are made of metal materials.
